(19) United States
(12) Patent Application Publication
(10) Pub. No.: US 2025/0160128 A1
(43) Pub. Date: May 15, 2025

(54) DISPLAY DEVICE

(71) Applicant: Samsung Display Co., LTD., Yongin-si (KR)

(72) Inventors: Suk Hoon KU, Yongin-si (KR); Dae Yong KIM, Yongin-si (KR); Sang Yeol KIM, Yongin-si (KR); Jin Taek KIM, Yongin-si (KR); Yong Tae CHO, Yongin-si (KR); Hyung Uk CHO, Yongin-si (KR)

(21) Appl. No.: 18/823,522

(22) Filed: Sep. 3, 2024

(30) Foreign Application Priority Data
Nov. 13, 2023 (KR) 10-2023-0156653

(51) Int. Cl. H10K 59/122

(52) U.S. Cl. CPC H10K 59/122

(57) ABSTRACT

A display device includes: a first electrode; a pixel defining layer on the first electrode; a separation layer on the pixel defining layer; an emission structure on the first electrode and the separation layer; and a second electrode on the emission structure, wherein the separation layer comprises a first separation layer on the pixel defining layer and having a first width, and a second separation layer on the first separation layer and having a second width greater than the first width, wherein the emission structure includes a first layer having a first thickness, and a second layer having a second thickness greater than the first thickness, and wherein the second separation layer is between the first layer and the second layer.

### CROSS-REFERENCE TO RELATED APPLICATION

The present application claims priority to and the benefit of Korean Patent Application No. 10-2023-0156653, filed on Nov. 13, 2023, in the Korean Intellectual Property, the entire disclosure of which is incorporated herein by reference.

### BACKGROUND

### 1. Field

Aspects of some embodiments of the present disclosure relate to a display device.

### 2. Description of the Related Art

Recently, as interest in information display increases, research and development on display devices have been continuously conducted.

The above information disclosed in this Background section is only for enhancement of understanding of the background and therefore the information discussed in this Background section does not necessarily constitute prior art.

### SUMMARY

Aspects of some embodiments of the present disclosure include a display device with relatively improved reliability, and a method of fabricating the display device.

According to some embodiments of the present disclosure, a display device includes: a first electrode, a pixel defining layer on the first electrode, a separation layer on the pixel defining layer, an emission structure on the first electrode and the separation layer, and a second electrode on the emission structure. According to some embodiments, the separation layer may include a first separation layer on the pixel defining layer and having a first width, and a second separation layer on the first separation layer and having a second width greater than the first width. According to some embodiments, the emission structure includes a first layer having a first thickness, and a second layer having a second thickness greater than the first thickness. According to some embodiments, the second separation layer may be between the first layer and the second layer.

According to some embodiments, a thickness of the first separation layer may be greater than the first thickness.

According to some embodiments, a thickness of the first separation layer may be less than a sum of the first thickness and the second thickness.

According to some embodiments, the first layer may be between the pixel defining layer and the second separation layer.

According to some embodiments, the separation layer may further include a third separation layer on the second separation layer and having a third width less than the second width, and a fourth separation layer on the third separation layer and having a fourth width greater than the third width.

According to some embodiments, the second layer may be between the second separation layer and the fourth separation layer.

According to some embodiments, the emission structure may further include a third layer having a third thickness less than the second thickness, and a fourth layer having a fourth thickness greater than the third thickness.

According to some embodiments, the fourth separation layer may be between the third layer and the fourth layer.

According to some embodiments, the third layer may be between the second layer and the fourth separation layer.

According to some embodiments, a thickness of the third separation layer may be greater than the third thickness.

According to some embodiments, a thickness of the third separation layer may be less than a sum of the third thickness and the fourth thickness.

According to some embodiments of the present disclosure, a display device includes: a first electrode, a pixel defining layer on the first electrode, a separation layer on the pixel defining layer, an emission structure on the first electrode and the separation layer, and a second electrode on the emission structure. According to some embodiments, the separation may include a first separation layer having a first width, and a second separation layer having a second width greater than the first width. According to some embodiments, the emission structure may include a first layer between the pixel defining layer and a first surface of the second separation layer, and a second layer on the a second surface of the second separation layer. According to some embodiments, an electrical conductivity of the first layer may be higher than an electrical conductivity of the second layer.

According to some embodiments, the first separation layer may be between the pixel defining layer and the second separation layer.

According to some embodiments, the separation layer may include a third separation layer having a third width less than the second width.

According to some embodiments, the third separation layer may be on the second surface of the second separation layer.

According to some embodiments, the separation layer may further include a fourth separation layer having a fourth width greater than the third width.

According to some embodiments, the third separation layer may be between the second separation layer and the fourth separation layer.

According to some embodiments, the emission structure may further include a third layer between the second surface of the second separation layer and a first surface of the fourth separation layer.

According to some embodiments, the emission structure may further include a fourth layer on a second surface of the fourth separation layer.

According to some embodiments, an electrical conductivity of the third layer may be higher than an electrical conductivity of the fourth layer.

Details of various embodiments are included in the detailed descriptions and drawings.

### BRIEF DESCRIPTION OF DRAWINGS

The above and other aspects and features of embodiments according to the present disclosure will become more apparent by describing, in further detail, aspects of some embodiments thereof with reference to the accompanying drawings, in which:

FIG. 1 is a block diagram of a display device according to some embodiments.

FIG. 2 is a block diagram of any one of sub-pixels of FIG. 1 according to some embodiments.

FIG. 3 is a circuit diagram of a sub-pixel of FIG. 2 according to some embodiments.

FIG. 4 is a plan view of a display panel of FIG. 1 according to some embodiments.

FIG. 5 is an exploded perspective view of a portion of a display panel of FIG. 4 according to some embodiments.

FIG. 6 is a plan view of any one of pixels of FIG. 5 according to some embodiments.

FIG. 7 is a sectional view taken line I-I′ of FIG. 6 according to some embodiments.

FIG. 8 is a sectional view of a separation layer and an emission structure of FIG. 7 according to some embodiments.

FIG. 9 is a sectional view of a separation layer and an emission structure of FIG. 7 according to some embodiments.

FIG. 10 is a sectional view of a separation layer and an emission structure of FIG. 7 according to some embodiments.

FIG. 11 is a sectional view of an emission structure included in any one of first to third light emitting elements of FIG. 7 according to some embodiments.

FIG. 12 is a sectional view of an emission structure included in any one of first to third light emitting elements of FIG. 7 according to some embodiments.

FIG. 13 is a plan view of any one of pixels of FIG. 5 according to some embodiments.

FIG. 14 is a plan view of any one of pixels of FIG. 5 according to some embodiments.

FIG. 15 is a block diagram of a display system according to some embodiments.

FIG. 16 is a perspective view of an application example of a display system of FIG. 15 according to some embodiments.

FIG. 17 is a diagram of a head-mounted display device of FIG. 16 that is worn on a user according to some embodiments.

### DETAILED DESCRIPTION

Aspects of some embodiments of the present disclosure now will be described more fully hereinafter with reference to the accompanying drawings, in which various embodiments thereof are shown. The present disclosure may, however, be embodied in many different forms, and should not be construed as limited to the embodiments described herein. Rather, these embodiments are provided so that this disclosure will be more thorough and more complete, and will more fully convey the scope of embodiments according to the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or combination of a, b, and/or c. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, aspects of some embodiments of the present disclosure will be described in more detail with reference to the accompanying drawings.

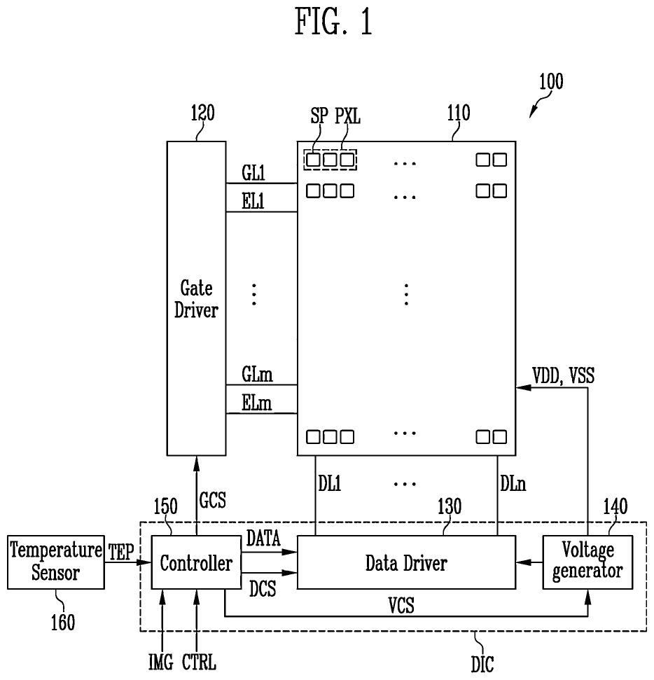

FIG. 1 is a block diagram of a display device according to some embodiments.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light in a specific color such as red, green, blue, cyan, magenta, or yellow. Two or more sub-pixels among the sub-pixels SP may form one pixel PXL. For example, as illustrated in FIG. 1, three sub-pixels SP may form one pixel PXL.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. According to some embodiments, the gate control signal GCS may include a start signal instructing each frame to start, a horizontal synchronization signal for outputting gate signals in synchronization with a timing at which data signals are applied, and the like.

According to some embodiments, there may be further provided first to m-th emission control lines EL1 to ELm connected to the sub-pixels SP in the row direction. In this case, the gate driver 120 may include an emission control driver configured to control the first to m-th emission control lines EL1 to ELm. The emission control driver may operate under the control of the controller 150.

The gate driver 120 may be located on one side of the display panel 110. However, embodiments are not limited to the aforementioned example. For example, the gate driver 120 may be divided into two or more drivers that are physically and/or logically distinguished from each other. The drivers may be located on a first side of the display panel 110 and a second side of the display panel 110 opposite to the first side. As such, the gate driver 120 may be arranged around the display panel 110 in various forms depending on embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may be operated in response to the data control signal DCS. According to some embodiments, the data control signal DCS may include a source start pulse, a source shift clock, a source output enable signal, and the like.

The data driver 130 may apply, using voltages from the voltage generator 140, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLm. Hence, the corresponding sub-pixels SP may generate light corresponding to the data signals. As a result, an image may be displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages and provide the generated voltages to components of the display device 100. For example, the voltage generator 140 may receive an input voltage from an external device provided outside the display device 100, adjust the received voltage, and regulate the adjusted voltage, thus generating a plurality of voltages.

The voltage generator 140 may generate a first power voltage VDD and a second power voltage VSS. The generated first and second power voltages VDD and VSS may be provided to the sub-pixels SP. The first power voltage VDD may have a relatively high voltage level. The second power voltage VSS may have a voltage level lower than the first power voltage VDD. According to some embodiments, the first power voltage VDD or the second power voltage VSS may be provided by an external device of the display device 100.

In addition, the voltage generator 140 may generate various voltages. For example, the voltage generator 140 may generate an initialization voltage to be applied to the sub-pixels SP. For example, during a sensing operation for sensing electrical characteristics of transistors and/or light emitting elements of the sub-pixels SP, a certain reference voltage may be applied to each of the first to n-th data lines DL1 to DLn. The voltage generator 140 may generate the reference voltage.

The controller 150 may control overall operations of the display device 100. The controller 150 may receive input image data IMG and a control signal CTRL for controlling an operation of displaying the input image data IMG from an external device. The controller 150 may provide a gate control signal GCS, a data control signal DCS, and a voltage control signal VCS, in response to the control signal CTRL.

The controller 150 may convert the input image data IMG to be suitable for the display device 100 or the display panel 110 and thus output image data DATA. According to some embodiments, the controller 150 may align the input image data IMG to be suitable for the sub-pixels SP on a row basis and then output the image data DATA.

Two or more components of the data driver 130, the voltage generator 140, and the controller 150 may be mounted into a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. According to some embodiments, at least one of the data driver 130, the voltage generator 140, or the controller 150 may be provided as a component separated from the driver integrated circuit DIC.

The display device 100 may include at least one temperature sensor 160. The temperature sensor 160 is configured to sense a peripheral temperature and generate temperature data TEP indicating the sensed temperature. According to some embodiments, the temperature sensor 160 may be located adjacent to the display panel 110 and/or the driver integrated circuit DIC.

The controller 150 may control various operations of the display device 100 in response to the temperature data TEP. According to some embodiments, the controller 150 may adjust the luminance of an image outputted from the display panel 110 in response to the temperature data TEP. For example, the controller 150 may control components such as the data driver 130 and/or the voltage generator 140, thus adjusting data signals and the first and second power voltages VDD and VSS.

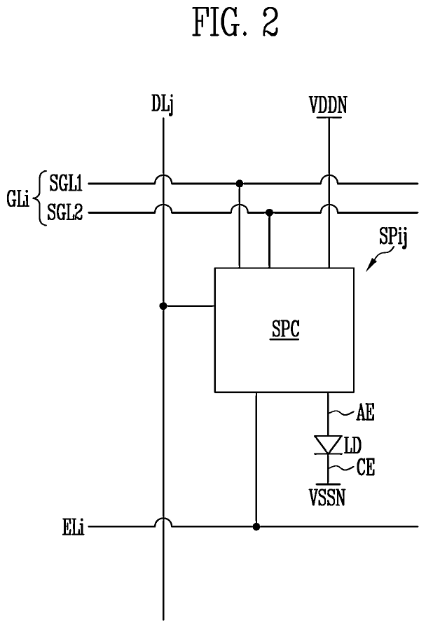

FIG. 2 is a block diagram of any one of sub-pixels of FIG. 1 according to some embodiments. In FIG. 2, there is illustrated a sub-pixel SPij located on an i-th row (where i is an integer identical to or greater than 1 and identical to or less than m) and a j-th column (where j is an integer identical to or greater than 1 and identical to or less than n).

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN is a node provided to transmit the first power voltage VDD of FIG. 1. The second power voltage node VSSN is a node provided to transmit the second power voltage VSS.

An anode electrode AE of the light emitting element LD may be connected to the first power voltage node VDDN through the sub-pixel circuit SPC. A cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GL1 among the first to m-th gate lines GL1 to GLm of FIG. 1, an i-th emission control line Eli among the first to m-th emission control lines EL1 to ELm of FIG. 1, and a j-th data line DLj among the first to n-th data lines DL1 to DLn of FIG. 1. The sub-pixel circuit SPC is configured to control the light emitting element LD in response to signals received through the aforementioned signal lines.

The sub-pixel circuit SPC may operate in response to a gate signal received through the i-th gate line GL1. The i-th gate line GL1 may include one or more sub-gate lines. According to some embodiments, as illustrated in FIG. 2, the i-th gate line GL1 may include first and second sub-gate lines SGL1 and SGL2. The sub-pixel circuit SPC may operate in response to gate signals received through the first and second sub-gate lines SGL1 and SGL2. As such, in the case where the i-th gate line GL1 include two or more sub-gate lines, the sub-pixel circuit SPC may operate in response to gate signals received through the corresponding sub-gate lines.

The sub-pixel circuit SPC may operate in response to an emission control signal received through the i-emission control line ELi. According to some embodiments, the i-th emission control line ELi may include one or more sub-emission control lines. In the case where the i-th emission control line ELi include two or more sub-emission control lines, the sub-pixel circuit SPC may operate in response to emission control signals received through the corresponding sub-emission control lines.

The sub-pixel circuit SPC may receive a data signal through a j-th data line DLj. The sub-pixel circuit SPC may store a voltage corresponding to the data signal in response to at least one of gate signals received through the first or second sub-gate lines SGL1 or SGL2. The sub-pixel circuit SPC may adjust current flowing from the first power voltage node VDDN to the second power voltage node VSSN through the light emitting element LD according to the stored voltage, in response to the emission control signal received through the i-th emission control line ELi. Therefore, the light emitting element LD may emit light at a luminance corresponding to the data signal.

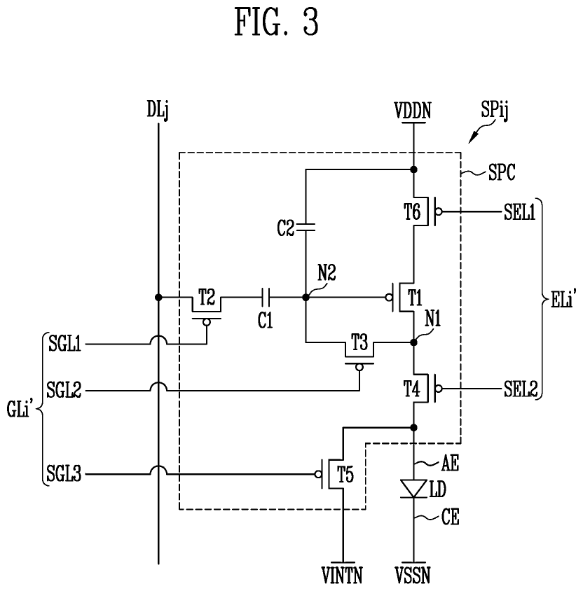

FIG. 3 is a circuit diagram of a sub-pixel of FIG. 2 according to some embodiments.

Referring to FIG. 3, the sub-pixel SPij may include a sub-pixel circuit SPC and a light emitting element LD.

The sub-pixel circuit SPC may be connected to an i-th gate line GL1′, an i-th emission control line ELi′, and a j-th data line DLj. Compared to the i-th gate line GL1 of FIG. 2, the i-th gate line GL1′ may further include a third sub-gate line SGL3. Compared to the i-th emission control line ELi of FIG. 2, the i-emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected between the first power node VDDN and the first node N1. A gate of the first transistor T1 may be connected to a second node N2. Hence, the first transistor T1 may be turned on depending on the voltage level of the second node N2. The first transistor T1 may be referred to as a driving transistor.

The second transistor T2 may be connected between the j-th data line DLj and the second node N2. A gate of the second transistor T2 may be connected to a first sub-gate line SGL1. Hence, the second transistor T2 may be turned on in response to a gate signal of the first sub-gate line SGL1. The second transistor T2 may be referred to as a switching transistor.

The third transistor T3 may be connected between the first node N1 and the second node N2. A gate of the third transistor T3 may be connected to a second sub-gate line SGL2. Hence, the third transistor T3 may be turned on in response to a gate signal of the second sub-gate line SGL2.

The fourth transistor T4 may be connected between the first node N1 and the anode electrode AE of the light emitting element LD. A gate of the fourth transistor T4 may be connected to the second sub-emission control line SEL2. Hence, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN is configured to transmit an initialization voltage. According to some embodiments, the initialization voltage may be provided by the voltage generator 140 of FIG. 1. According to some embodiments, the initialization voltage may be provided by an external device of the display device 100. A gate of the fifth transistor T5 may be connected to a third sub-gate line SGL3. Hence, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1. Hence, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the sub-pixel circuit SPC may include the first to sixth transistors T1 to T6 and the first and second capacitors C1 and C2. However, embodiments are not limited to the aforementioned example. The sub-pixel circuit SPC may be implemented as any one of various forms of circuits each including a plurality of transistors and one or more capacitors. For example, the sub-pixel circuit SPC may include two transistors and one capacitor. Depending on embodiments of the sub-pixel circuit SPC, the number of sub-gate lines included in the i-th gate line GL1′ and the number of sub-emission control lines included in the i-th emission control line ELi′ may vary.

The first to sixth transistors T1 to T6 may be formed of P-type transistors. Each of the first to sixth transistors T1 to T6 may be formed of a metal oxide silicon field effect transistor (MOSFET). However, embodiments are not limited to the aforementioned example. For example, at least one of the first to sixth transistors T1 to T6 may be replaced with to an N-type transistor.

According to some embodiments, the first to sixth transistors T1 to T6 may include an amorphous silicon semiconductor, a monocrystalline silicon semiconductor, a polycrystalline silicon semiconductor, an oxide semiconductor, or the like.

The light emitting element LD may include the anode electrode AE, the cathode electrode CE, and an emission layer. The emission layer may be located between the anode electrode AE and the cathode electrode CE. When emission control signals of the first and second sub-emission control lines SEL1 and SEL2 are enabled to a low level after a data signal transmitted through the j-th data line DLj is reflected in the voltage of the second node N2, the fourth and sixth transistors T4 and T6 may be turned on. The first transistor T1 may be turned on in response to the voltage of the second node N2, so that current may flow from the first power voltage node VDDN to the second power voltage node VSSN. The light emitting element LD may emit light corresponding to the amount of current.

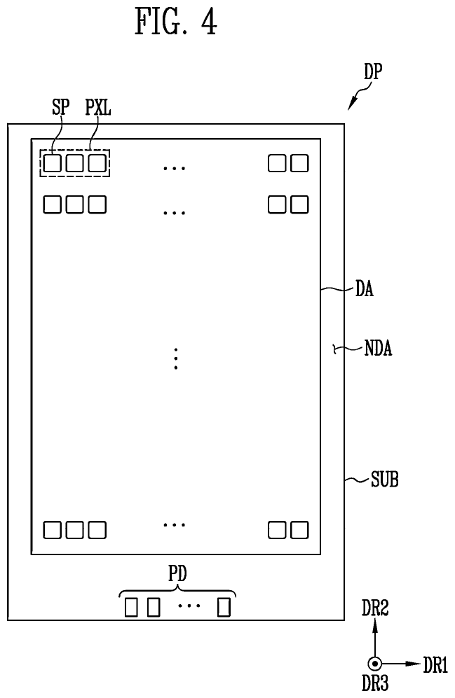

FIG. 4 is a plan view of a display panel of FIG. 1 according to some embodiments.

Referring to FIG. 4, an example display panel DP corresponding to the display panel 110 depicted in FIG. 1 may include a display area DA and a non-display area NDA. The display panel DP may display an image through the display area DA. The non-display area NDA may be arranged around (e.g., in a periphery or outside a footprint of) the display area DA.

The display panel DP may include a substrate SUB, sub-pixels SP, and pads PD.

In the case where the display panel DP is used as a display screen for a head mounted display (HMD), a virtual reality (VR) device, a mixed reality (MR) device, an augmented reality (AR) device, and the like, the display panel DP may be positioned extremely close to the eyes of the user. In this case, relatively high-density sub-pixels SP may be required. To increase the pixel density of the sub-pixels SP, the substrate SUB may be provided as a silicon substrate. The sub-pixels SP and/or the display panel DP may be formed on the substrate SUB that is a silicon substrate. The display device 100 (refer to FIG. 1) including the display panel DP formed on the substrate SUB that is a silicon substrate may be referred to as an OLED on Silicon (OLEDoS) display device.

The sub-pixels SPX may be located in the display area DA on the substrate SUB. The sub-pixels SP may be arranged in the form of a matrix along a first direction DR1 and a second direction DR2 intersecting with the first direction DR1. However, embodiments are not limited to the aforementioned example. For example, the sub-pixels SP may be arranged in a zigzag pattern in the first direction DR1 and the second direction DR2. For example, the sub-pixels SP may be arranged in the form of a PENTILETM. The first direction DR1 may refer to a row direction, and the second direction DR2 may refer to a column direction.

Two or more sub-pixels among the sub-pixels SP may form one pixel PXL.

Components for controlling the sub-pixels SP may be located in the non-display area NDA on the substrate SUB. For example, connected to the sub-pixels SP, lines such as the first to m-th gate lines GL1 to GLm and the first to n-th data lines DL1 to DLn of FIG. 1 may be located in the non-display area NDA.

At least one of the gate driver 120, the data driver 130, the voltage generator 140, the controller 150, or the temperature sensor 160 of FIG. 1 may be integrated in the non-display area NDA of the display panel DP. According to some embodiments, the gate driver 120 of FIG. 1 may be mounted on the display panel DP and positioned in the non-display area NDA. According to some embodiments, the gate driver 120 may be implemented as an integrated circuit separated from the display panel DP. According to some embodiments, the temperature sensor 160 may be positioned in the non-display area NDA to sense the temperature of the display panel DP.

The pads PD may be located in the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DP with other components of the display device 100 (refer to FIG. 1). According to some embodiments, voltages and signals required for the operation of the components included in the display panel DP may be provided through the pads PD from the driver integrated circuit DIC of FIG. 1. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in the case where the gate driver 120 is mounted on the display panel DP, the gate control signal GCS may be transmitted from the driver integrated circuit DIC to the gate driver 120 through the pads PD.

According to some embodiments, a circuit board may be electrically connected to the pads PD by a conductive adhesive component such as an anisotropic conductive film. Here, the circuit board may be a flexible circuit board (FPCB) or flexible film that is made of flexible material. The driver integrated circuit DIC may be mounted on the circuit board and be electrically connected to the pads PD.

According to some embodiments, the display area DA may have various shapes. The display area DA may have a closed-loop shape, including linear and/or curved sides. For example, the display area DA may have shapes such as polygons, circles, semicircles, ellipses, and the like.

According to some embodiments, the display panel DP may have a planar display surface. According to some embodiments, the display panel DP may have a display surface that is least partially rounded. According to some embodiments, the display panel DP may be bendable, foldable, or rollable. In the aforementioned cases, the display panel DP and/or the substrate SUB may include materials having flexible properties.

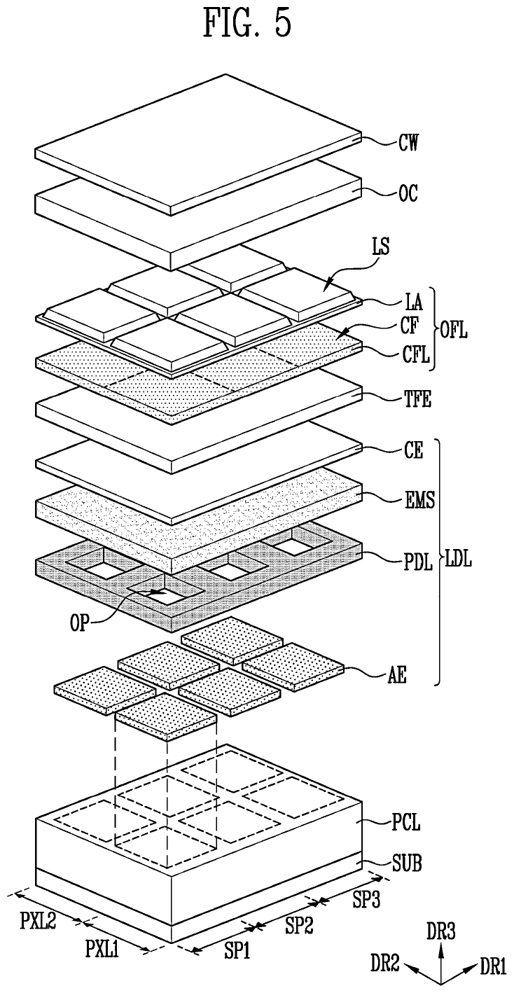

FIG. 5 is an exploded perspective view of a portion of a display panel of FIG. 4 according to some embodiments. In FIG. 5, for the sake of clear and concise explanation, there is schematically illustrated a portion of the display panel DP corresponding to two pixels PXL1 and PXL2 among the pixels PXL of FIG. 4. The remaining portions of the display panel DP corresponding to the other pixels may also be configured in the same manner.

Referring to FIGS. 4 and 5, each of the first and second pixels PXL1 and PXL2 may include first to third sub-pixels SP1, SP2, and SP3. However, embodiments are not limited to the aforementioned example. For example, each of the first and second pixels PXL1 and PXL2 may include four sub-pixels, or may include two sub-pixels.

In FIG. 5 there is illustrated the case where the first to third sub-pixels SP1, SP2, and SP3 have rectangular shapes and the same size when viewed in a third direction DR3 intersecting with the first and second directions DR1 and DR2. However, embodiments are not limited to the aforementioned example. The first to third sub-pixels SP1, SP2, and SP3 may be modified to have various shapes.

The display panel DP may include a substrate SUB, a pixel circuit layer PCL, a light-emitting-element layer LDL, an encapsulation layer TFE, an optical functional layer OFL, an overcoat layer OC, and a cover window CW.

According to some embodiments, the substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. According to some embodiments, the substrate SUB may include a glass substrate. According to some embodiments, the substrate SUB may include a polyimide (polyimide) substrate.

The pixel circuit layer PCL may be located on the substrate SUB. The substrate SUB and/or the pixel circuit layer PCL may include insulating layers, and conductive patterns located between the insulating layers. The conductive patterns of the pixel circuit layer PCL may function as at least some of the circuit components, lines, or the like. The conductive patterns may include copper, but embodiments are not limited thereto.

The circuit elements may include respective sub-pixel circuits SPC (refer to FIG. 2) of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. According to some embodiments, in the case where the substrate SUB is formed of a silicon substrate, the semiconductor portion may be included in the substrate SUB, and the gate electrode may be included in the pixel circuit layer PCL as a conductive pattern of the pixel circuit layer PCL. According to some embodiments, in the case where the substrate SUB is formed of a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined in the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1, SP2, and SP3, for example, a gate line, an emission control line, and a data line. The lines may further include a line connected to the first power voltage node VDDN of FIG. 2. The lines may further include a line connected to the second power voltage node VSSN of FIG. 2.

The light-emitting-element layer LDL may include anode electrodes AE, a pixel defining layer PDL, an emission structure EMS, and a cathode electrode CE.

The anode electrodes AE may be located on the pixel circuit layer PCL. The anode electrodes AE may be electrically connected to circuit elements of the pixel circuit layer PCL. The anode electrodes AE may include opaque conductive material capable of reflecting light, but embodiments are not limited thereto.

The pixel defining layer PDL may be located on the anode electrode AE. The pixel defining layer PDL may include openings OP that expose respective portions of the anode electrodes AE. The openings OP in the pixel defining layer PDL may be understood as respective emission areas corresponding to the first to third sub-pixels SP1 to SP3.

According to some embodiments, the pixel defining layer PDL may include inorganic material. In this case, the pixel defining layer PDL may include a plurality of inorganic layers stacked on top of one another. For example, the pixel defining layer PDL may include silicon oxide (SiOₓ) and silicon nitride (SiNₓ). According to some embodiments, the pixel defining layer PDL may include organic material. However, the material of the pixel defining layer PDL is not limited to the aforementioned examples.

The emission structure EMS may be located on the anode electrodes AE exposed through the openings OP in the pixel defining layer PDL. The emission structure EMS may include an emission layer configured to generate light, an electron transport layer configured to transport electrons, and a hole transport layer configured to transport holes.

According to some embodiments, the emission structure EMS may fill the openings OP in the pixel defining layer PDL and be arranged on an overall surface of an upper portion of the pixel defining layer PDL. The emission structure EMS may extend over the first to third sub-pixels SP1 to SP3. In this case, at least some of the layers in the emission structure EMS may be divided (interrupted) or bent on boundaries between the first to third sub-pixels SP1 to SP3. However, embodiments are not limited to the aforementioned example. For instance, portions of the emission structure EMS corresponding to the first to third sub-pixels SP1 to SP3 may be separated from each other, and each of the separated portions of the emission structure EMS may be located in the corresponding opening OP in the pixel defining layer PDL.

The cathode electrode CE may be located on the emission structure EMS. The cathode electrode CE may extend over the first to third sub-pixels SP1 to SP3. As such, the cathode electrode CE may be provided as a common electrode for the first to third sub-pixels SP1 to SP3.

The cathode electrode CE may be a thin-film metal layer having a thickness allowing light emitted from the emission structure EMS to pass therethrough. The cathode electrode CE may be made of a metal material having a relatively small thickness, or a transparent conductive material. According to some embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. According to some embodiments, the cathode electrode CE may include at least one of silver (Ag), magnesium (Mg), or a compound thereof. However, the material of the cathode electrode CE is not limited to the foregoing example.

Any one of the anode electrodes AE, a portion of the emission structure EMS that overlap the any one anode electrode AE, and a portion of the cathode electrode CE that overlaps the portion of the emission structure EMS can be understood as constituting one light emitting element LD (refer to FIG. 2). Each of the light emitting elements of the first to third sub-pixels SP1 to SP3 may include one anode electrode AE, a portion of the emission structure EMS that overlaps the one anode electrode AE, and a portion of the cathode electrode CE that overlaps the portion of the emission structure. In each of the first to third sub-pixels SP1 to SP3, holes injected from the anode electrode AE and electrons injected from the cathode electrode CE are transported into the emission layer of the emission structure EMS, thus forming excitons. When the excitons make a transition from an excited state to a ground state, light can be generated. Depending on the amount of current flowing through the emission layer, the luminance of light may be determined. Depending on the configuration of the emission layer, the wavelength range of light to be generated may be determined.

The encapsulation layer TFE may be located on the cathode electrode CE. The encapsulation layer TFE may cover the light-emitting-element layer LDL and/or the pixel circuit layer PCL. The encapsulation layer TFE may be configured to prevent or reduce instances of contaminants such as oxygen and/or water or the like penetrating into the light-emitting-element layer LDL. According to some embodiments, the encapsulation layer TFE may include a structure formed by alternately stacking one or more inorganic layers and one or more organic layers. For example, the inorganic layer may include silicon nitride, silicon oxide, silicon oxynitride (SiOₓN_{y}), or the like. For example, the organic layer may include organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, the materials of the organic layer and the inorganic layer of the encapsulation layer TFE are limited to the aforementioned examples.

The encapsulation layer TFE may further include a thin film, including aluminum oxide (AlOₓ), to enhance the encapsulation efficiency of the encapsulation layer TFE. The thin film including aluminum oxide may be positioned on an upper surface of the encapsulation layer TFE that faces the optical functional layer OFL and/or under a lower surface of the encapsulation layer TFE that faces the light-emitting-element layer LDL.

The thin film including aluminum oxide may be formed through an atomic layer deposition (ALD) method. However, embodiments are not limited to the aforementioned example. The encapsulation layer TFE may further include a thin film formed of at least one of various materials suitable for enhancing the encapsulation efficiency.

The optical functional layer OFL may be located on the encapsulation layer TFE. The optical functional layer OFL may include a color filter layer CFL and a lens array LA.

The color filter layer CFL may be located between the encapsulation layer TFE and the lens array LA. The color filter layer CFL may be configured to filter light emitted from the emission structure EMS to selectively output light in a wavelength range or color corresponding to each sub-pixel. The color filter layer CFL may include color filters CF respectively corresponding to the first to third sub-pixels SP1 to SP3. Each of the color filters CF allows light within a wavelength range corresponding to the related sub-pixel to pass therethrough. For example, the color filter that corresponds to the first sub-pixel SP1 allows light in a red color to pass therethrough, the color filter that corresponds to the second sub-pixel SP2 allows light in a green color to pass therethrough, and the color filter that corresponds to the third sub-pixel SP3 allows light in a blue color to pass therethrough. Depending on the light emitted from the emission structure EMS of each sub-pixel, at least some of the color filters CF may be omitted.

The lens array LA may be located on the color filter layer CFL. The lens array LA may include lenses LS that respectively correspond to the first to third sub-pixels SP1 to SP3. Each of the lenses LS may output and direct light emitted from the emission structure EMS along an intended path, thus enhancing the light output efficiency. The lens array LA may have a relatively high refractive index. For example, the lens array LA may have a higher refractive index than the overcoat layer OC. According to some embodiments, the lenses LS may include organic material. According to some embodiments, the lenses LS may include acrylic material. However, the material of the lenses LS is not limited to the foregoing example.

According to some embodiments, compared to the openings OP of the pixel defining layer PDL, at least some of the color filters CF of the color filter layer CFL and at least some of the lenses LS of the lens array LA may be shifted in a direction parallel to the plane defined in the first and second directions DR1 and DR2. For example, in a central area of the display area DA, the center of each color filter and the center of each lens may be aligned or overlapped with the center of the corresponding opening OP of the pixel defining layer PDL. For example, in the central area of the display area DA, each opening OP of the pixel defining layer PDL may completely overlap the corresponding color filter of the color filter layer CFL and the corresponding lens of the lens array LA. In an area of the display area DA that is adjacent to the non-display area NDA, the center of the color filter and the center of the lens LS may be shifted in a plane direction from the center of the corresponding opening OP of the pixel defining layer PDL when viewed in the third direction DR3. For example, in the area adjacent to the non-display area NDA within the display area DA, each opening OP of the pixel defining layer PDL may partially overlap the corresponding color filter of the color filter layer CFL and the corresponding lens of the lens array LA. Accordingly, light emitted from the emission structure EMS in the central portion of the display area DA may be efficiently outputted in the normal direction of the display surface. Light emitted from the emission structure EMS around the perimeter of the display area DA may be efficiently outputted in a direction inclined at a certain angle with respect to the normal direction of the display surface.

The overcoat layer OC may be located on the lens array LA. The overcoat layer OC may cover the optical functional layer OFL, the encapsulation layer TFE, the emission structure EMS, and/or the pixel circuit layer PCL. The overcoat layer OC may include various materials suitable for protecting underlying layers from foreign substances such as dust, water, or the like. For example, the overcoat layer OC may include at least one of an inorganic insulating layer or an organic insulating layer. For example, the overcoat layer OC may include epoxy, but it is not limited thereto. The overcoat layer OC may have a lower refractive index than the lens array LA.

The cover window CW may be located on the overcoat layer OC. The cover window CW may be configured to protect underlying layers. The cover window CW may have a higher refractive index than the overcoat layer OC. The cover window CW may include glass, but embodiments are not limited thereto. For example, the cover window CW may be an encapsulation glass layer configured to protect components located thereunder. According to some embodiments, the cover window CW may be omitted.

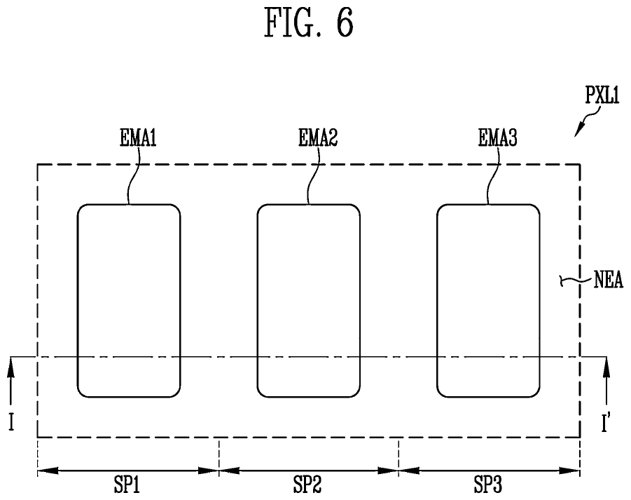

FIG. 6 is a plan view of any one of pixels of FIG. 5 according to some embodiments. In FIG. 6, for the sake of clear and concise explanation, the first pixel PXL1 of the first and second pixels PXL1 and PXL2 of FIG. 5 are schematically depicted. The other pixels may be configured in the same manner as the first pixel PXL1.

Referring to FIGS. 5 and 6, the first pixel PXL1 may include first to third sub-pixels SP1 to SP3 arranged in the first direction DR1.

The first sub-pixel SP1 may include a first emission area EMA1 and a non-emission area NEA formed around the first emission area EMA1. The second sub-pixel SP2 may include a second emission area EMA2 and a non-emission area NEA formed around the second emission area EMA2. The third sub-pixel SP3 may include a third emission area EMA3 and a non-emission area NEA formed around the third emission area EMA3.

The first emission area EMA1 may be an area where light is emitted from a portion of the emission structure EMS (refer to FIG. 5) that corresponds to the first sub-pixel SP1. The second emission area EMA2 may be an area where light is emitted from a portion of the emission structure EMS that corresponds to the second sub-pixel SP2. The third emission area EMA3 may be an area where light is emitted from a portion of the emission structure EMS that corresponds to the third sub-pixel SP3. As described with reference to FIG. 5, each emission area may be understood as being the opening OP of the pixel defining layer PDL corresponding to each of the first to third sub-pixels SP1 to SP3.

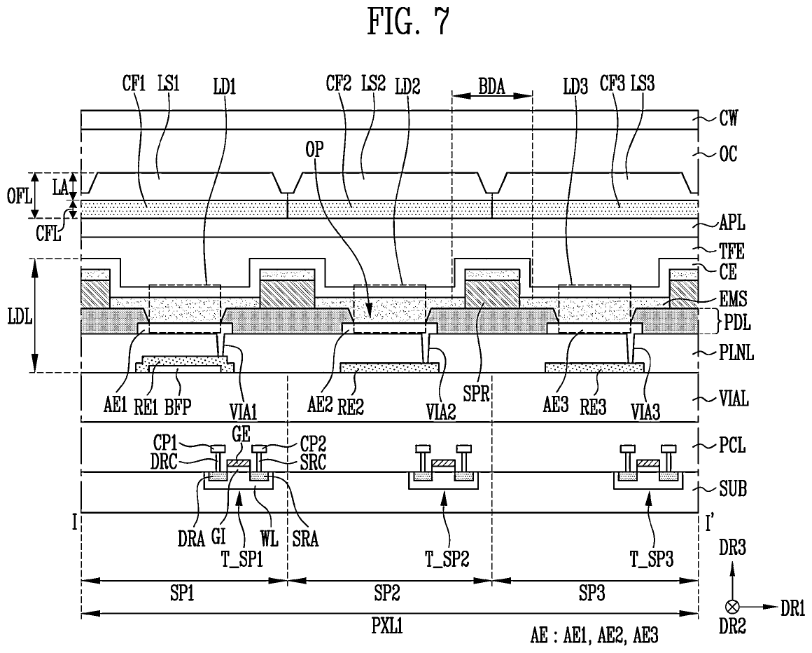

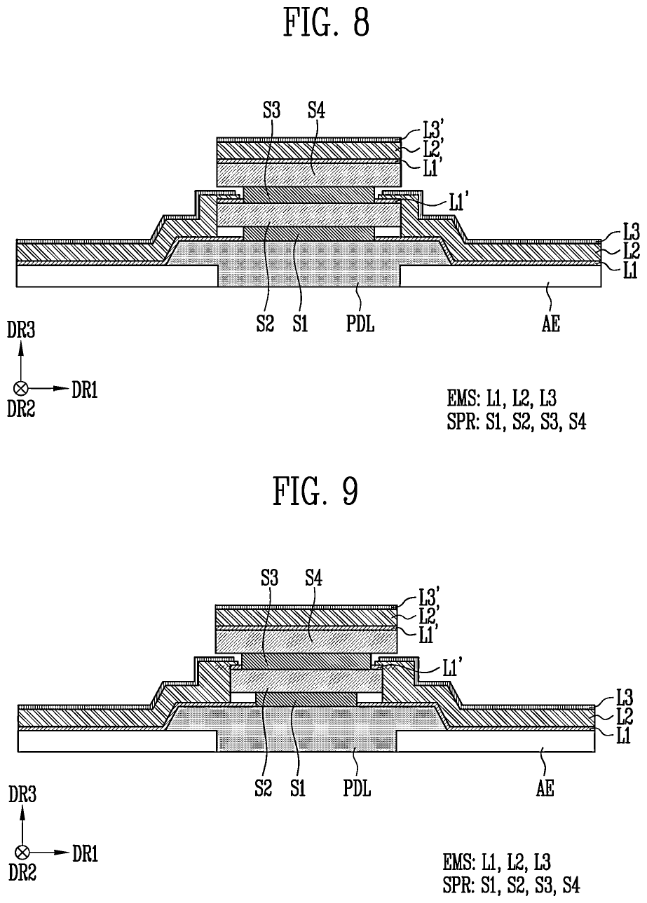

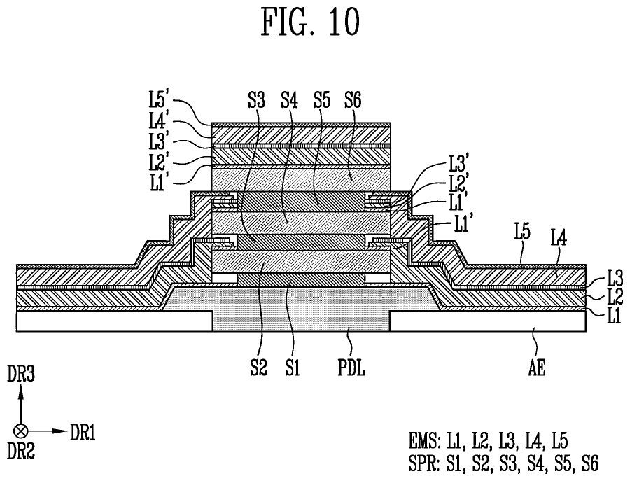

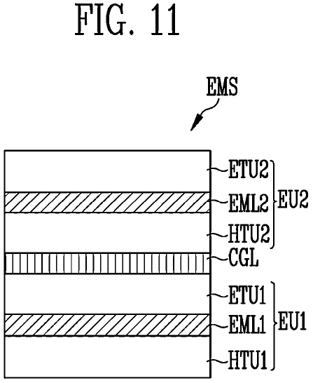

FIG. 7 is a sectional view taken line I-I′ of FIG. 6 according to some embodiments. FIG. 8 is a sectional view of a separation layer and an emission structure of FIG. 7 according to some embodiments. FIG. 9 is a sectional view of a separation layer and an emission structure of FIG. 7 according to some embodiments. FIG. 10 is a sectional view of a separation layer and an emission structure of FIG. 7 according to some embodiments.

Referring to FIG. 7, there are provided the substrate SUB and the pixel circuit layer PCL located on the substrate SUB.

The substrate SUB may include a silicon wafer substrate formed through a semiconductor process. For example, the substrate SUB may include silicon, germanium, and/or silicon-germanium.

The pixel circuit layer PCL may be located on the substrate SUB. The substrate SUB and the pixel circuit layer PCL may include respective circuit elements of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 2) of the first sub-pixel SP1. The transistor T_SP2 of the second sub-pixel SP2 may be any one of the transistors included in the sub-pixel circuit SPC of the second sub-pixel SP2. The transistor T_SP3 of the third sub-pixel SP3 may be any one of the transistors included in the sub-pixel circuit SPC of the third sub-pixel SP3. In FIG. 7, one of the transistors of each sub-pixel is illustrated for the sake of clear and concise explanation, and the remaining circuit circuits are omitted.

The transistor T_SP1 of the first sub-pixel SP1 may include a source area SRA, a drain area DRA, and a gate electrode GE.

The source area SRA and the drain area DRA may be located in the substrate SUB. Formed through an ion injection process, a well WL may be located in the substrate SUB. The source area SRA and the drain area DRA may be arranged to be spaced apart from each other in the well WL. An area between the source area SRA and the drain area DRA in the well WL may be defined as a channel area.

The gate electrode GE may overlap the channel area between the source area SRA and the drain area DRA, and may be located in the pixel circuit layer PCL. The gate electrode GE may be spaced apart from the well WL or the channel area by an insulating material such as a gate insulating layer GI. The gate electrode GE may include conductive material.

A plurality of layers included in the pixel circuit layer PCL may include insulating layers and conductive patterns located between the insulating layers. The conductive patterns may include first and second conductive patterns CP1 and CP2. The first conductive pattern CP1 may be electrically connected to the drain area DRA through a drain connector DRC passing through one or more insulating layers. The second conductive pattern CP2 may be electrically connected to the source area SRA through a source connector SRC passing through one or more insulating layers.

As the gate electrode GE and the first and second conductive patterns CP1 and CP2 are connected to other circuit elements and/or lines, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured in the same manner as the transistor T_SP1 of the first sub-pixel SP1.

As such, the substrate SUB and the pixel circuit layer PCL may include respective circuit elements of the first to third sub-pixels SP1 to SP3.

A via layer VAL may be located on the pixel circuit layer PCL. The via layer VIAL may cover the pixel circuit layer PCL, and have an overall even surface. The via layer VIAL may be configured to planarize stepped portions on the pixel circuit layer PCL. The via layer VIAL may include at least one of silicon oxide (SiOₓ), silicon nitride (SiNₓ), or silicon carbon nitride (SiCN), but embodiments are not limited thereto. The light-emitting-element layer LDL may be located on the via layer VIAL.

The light-emitting-element layer LDL may include first to third reflective electrodes RE1 to RE3, a planarization layer PLNL, first to third anode electrodes AE1 to AE3, the pixel defining layer PDL, the separation layer SPR, the emission structure EMS, and the cathode electrode CE.

The first to third reflective electrodes RE1 to RE3 may be respectively located in the first to third sub-pixels SP1 to SP3 on the via layer VIAL. Each of the first to third reflective electrodes RE1 to RE3 may be electrically connected to a circuit element located in the pixel circuit layer PCL through a corresponding via passing through the via layer VIAL.

The first to third reflective electrodes RE1 to RE3 may function as full mirrors provided to reflect light emitted from the emission structure EMS toward the display surface (or the cover window CW). The first to third reflective electrodes RE1 to RE3 may include metallic materials suitable for reflecting light. The first to third reflective electrodes RE1 to RE3 may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected from among the aforementioned materials, but embodiments are not limited thereto.

According to some embodiments, a connection electrode may be located under each of the first to third reflective electrodes RE1 to RE3. The connection electrode may enhance electrical connection characteristics between the corresponding reflective electrode and the corresponding circuit element of the pixel circuit layer PCL. The connection electrode may have a multilayer structure. The multilayer structure may include titanium (Ti), titanium nitride (TiN), tantalum nitride (TaN), and the like, but embodiments are not limited thereto. According to some embodiments, a corresponding reflective electrode may be positioned between multiple layers of the connection electrode.

A buffer pattern BFP may be located under at least one of the first to third reflective electrodes RE1 to RE3. The buffer pattern BFP may include inorganic material such as silicon carbon nitride, but embodiments are not limited thereto. As the buffer pattern BFP is located, the height of the corresponding reflective electrode in the third direction DR3 may be adjusted. For example, the buffer pattern BFP may be located between the first reflective electrode RE1 and the via layer VIAL, thus adjusting the height of the first reflective electrode RE1.

The first to third reflective electrodes RE1 to RE3 may function as full mirrors, and the cathode electrode CE may function as a half mirror. Light emitted from the emission layer of the emission structure EMS may be amplified, at least partially, by reciprocating between the corresponding reflective electrode and the cathode electrode CE. The amplified light can be output through the cathode electrode CE. In this way, the distance between each reflective electrode and the cathode electrode CE can be understood as a resonant distance for the light emitted from the emission layer of the corresponding emission structure EMS.

The first sub-pixel SP1 may have a resonant distance shorter than other sub-pixels due to the buffer pattern BFP. As such, the adjusted resonant distance makes it possible for light in a specific wavelength range (e.g., red color) to be efficiently amplified. Consequently, the first sub-pixel SP1 may effectively and efficiently output light in the corresponding wavelength range.

In FIG. 7, there is illustrated the case where the buffer pattern BFP is provided in the first sub-pixel SP1 but is not provided in the second and third sub-pixels SP2 and SP3, but embodiments are not limited thereto. The buffer pattern may also be provided in at least one of the second or third sub-pixels SP2 or SP3 so that the resonant distance of at least one of the second or third sub-pixels SP2 or SP3 can be adjusted. For example, the first to third sub-pixels SP1 to SP3 may respectively correspond to red, green, and blue. The distance between the first reflective electrode RE1 and the cathode electrode CE may be less than the distance between the second reflective electrode RE2 and the cathode electrode CE. The distance between the second reflective electrode RE2 and the cathode electrode CE may be less than the distance between the third reflective electrode RE3 and the cathode electrode CE.

To planarize the stepped portions between the first to third reflective electrodes RE1 to RE3, the planarization layer PLNL may be located on the via layer VIAL and the first to third reflective electrodes RE1 to RE3. The planarization layer PLNL may cover overall surfaces of the first to third reflective electrodes RE1 to RE3 and the via layer VIAL, and have an even surface. According to some embodiments, the planarization layer PLNL may be omitted.

On the planarization layer PLNL, the first to third anode electrodes AE1 to AE3 may be located, overlapping the first to third reflective electrodes RE1 to RE3, respectively. The first to third anode electrodes AE1 to AE3 may have shapes similar to the first to third emission areas EMA1 to EMA3 of FIG. 6 when viewed in the third direction DR3. The first to third anode electrodes AE1 to AE3 are respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

According to some embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), or indium tin zinc oxide (ITZO). However, the material of the first to third anode electrodes AE1 to AE3 is not limited to the aforementioned example. For example, the first to third anode electrodes AE1 to AE3 may include titanium nitride.

Insulating layers may be further provided to adjust the heights of one or more of the first to third anode electrodes AE1 to AE3. The insulating layers may be located between one or more of the first to third anode electrodes AE1 to AE3 and the corresponding reflective electrodes. In this case, the planarization layer PLNL and/or the buffer pattern BFP may be omitted. For example, the first to third sub-pixels SP1 to SP3 may respectively correspond to red, green, and blue. The distance between the first anode electrode AE1 and the cathode electrode CE may be less than the distance between the second anode electrode AE2 and the cathode electrode CE. The distance between the second anode electrode AE2 and the cathode electrode CE may be less than the distance between the third anode electrode AE3 and the cathode electrode CE.

The pixel defining layer PDL may be located on the planarization layer PLNL and portions of the first to third anode electrodes AE1 to AE3. The pixel defining layer PDL may include openings OP that expose respective portions of the first to third anode electrodes AE1 to AE3. The openings OP in the pixel defining layer PDL may define the respective emission areas of the first to third sub-pixels SP1 to SP3. As such, the pixel defining layer PDL may be placed in the non-emission area NEA of FIG. 6 and define the first to third emission areas EMA1 to EMA3 of FIG. 6.

According to some embodiments, the pixel defining layer PDL may include a plurality of inorganic insulating layers. Each of the inorganic insulating layers may include at least one of silicon oxide (SiOₓ) or silicon nitride (SiNₓ). For example, the pixel defining layer PDL may include first to third inorganic insulating layers that are successively stacked. The first to third inorganic insulating layers may respectively include silicon nitride, silicon oxide, and silicon nitride. However, embodiments are not limited thereto. The first to third insulating layers may have a stepped shape in an area adjacent to each of the openings OP, but embodiments are not limited thereto.

A separation layer SPR may be provided in a boundary area BDA between adjacent sub-pixels. For example, the separation layer SPR may be provided in each of the boundary areas between the sub-pixels SP of FIG. 4. The separation layer SPR may be provided on the pixel defining layer PDL.

The separation layer SPR may result in creation of discontinuous portions in the emission structure EMS in the boundary area BDA. For example, the emission structure EMS may be divided (interrupted) or bent in the boundary area BDA by the separation layer SPR. Consequently, during the operation of the display panel DP, current leaking from each of the first to third sub-pixels SP1 to SP3 to the adjacent sub-pixel through the layers included in the emission structure EMS may be reduced. As a result, the first to third light emitting elements LD1 to LD3 may operate with relatively high reliability.

Referring to FIG. 8, the separation layer SPR may be configured of a plurality of layers. For example, the separation layer SPR may include a first separation layer S1, a second separation layer S2, a third separation layer S3, and/or a fourth separation layer S4.

The first separation layer S1 may be placed on the pixel defining layer PDL. The first separation layer S1 may be located between the pixel defining layer PDL and the second separation layer S2. The first separation layer S1 may be located between the pixel defining layer PDL and a first surface of the second separation layer S2. A first surface of the first separation layer S1 may contact the pixel defining layer PDL, and a second surface of the first separation layer S1 may contact the first surface of the second separation layer S2.

The second separation layer S2 may be located on the first separation layer S1. The second separation layer S2 may be located between the first separation layer S1 and the third separation layer S3. The second separation layer S2 may be located between the second surface of the first separation layer S1 and a first surface of the third separation layer S3. The first surface of the second separation layer S2 may contact the second surface of the first separation layer S1, and a second surface of the second separation layer S2 may contact the first surface of the third separation layer S3.

The third separation layer S3 may be located on the second separation layer S2. The third separation layer S3 may be located between the second separation layer S2 and the fourth separation layer S4. The third separation layer S3 may be located between the second surface of the second separation layer S2 and a first surface of the fourth separation layer S4. The first surface of the third separation layer S3 may contact the second surface of the second separation layer S2, and a second surface of the third separation layer S3 may contact the first surface of the fourth separation layer S4.

The fourth separation layer S4 may be located on the third separation layer S3. The first surface of the fourth separation layer S4 may contact the second surface of the third separation layer S3.

A first width of the first separation layer S1 with respect to the first direction DR1 may be different from a second width of the second separation layer S2 with respect to the first direction DR1. For example, the first width of the first separation layer S1 with respect to the first direction DR1 may be less than the second width of the second separation layer S2 with respect to the first direction DR1.

The second width of the second separation layer S2 with respect to the first direction DR1 may be different from a third width of the third separation layer S3 with respect to the first direction DR1. For example, the second width of the second separation layer S2 with respect to the first direction DR1 may be greater than the third width of the third separation layer S3 with respect to the first direction DR1.

The third width of the third separation layer S3 with respect to the first direction DR1 may be different from a fourth width of the fourth separation layer S4 with respect to the first direction DR1. For example, the third width of the third separation layer S3 with respect to the first direction DR1 may be less than the fourth width of the fourth separation layer S4 with respect to the first direction DR1.

According to some embodiments, the first width of the first separation layer S1 with respect to the first direction DR1 may be the same as the third width of the third separation layer S3 with respect to the first direction DR1. The second width of the second separation layer S2 with respect to the first direction DR1 may be the same as the fourth width of the fourth separation layer S4 with respect to the first direction DR1. However, embodiments are not limited to the aforementioned example. As shown in FIG. 9, the first width of the first separation layer S1 with respect to the first direction DR1 may be less than the third width of the third separation layer S3 with respect to the first direction DR1. The second width of the second separation layer S2 with respect to the first direction DR1 may be less than the fourth width of the fourth separation layer S4 with respect to the first direction DR1.

The first to fourth separation layers S1, S2, S3, and S4 may each include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The first separation layer S1 and the second separation layer S2 may respectively include different materials. The second separation layer S2 and the third separation layer S3 may respectively include different materials. The third separation layer S3 and the fourth separation layer S4 may respectively include different materials. The first separation layer S1 and the third separation layer S3 may have the same material. The second separation layer S2 and the fourth separation layer S4 may have the same material. For example, the first separation layer S1 and the third separation layer S3 may be formed of silicon oxide (SiOₓ), and the second separation layer S2 and the fourth separation layer S4 may be formed of silicon nitride (SiNₓ), but embodiments are not limited thereto.

The emission structure EMS may be located on the anode electrodes AE and the separation layer SPR. The emission structure EMS may be located on the anode electrodes AE exposed from the pixel defining layer PDL. The emission structure EMS may be located overall in the first to third sub-pixels SP1 to SP3. Some or entirety of a plurality of layers included in the emission structure EMS may be divided or bent in the boundary area BDA by the separation layer SPR.

The emission structure EMS may be configured of the plurality of layers. For example, the emission structure EMS may include a first layer L1, a second layer L2, and/or a third layer L3. The second layer L2 may be located between the first layer L1 and the third layer L3.

The first layer L1 may be located on the anode electrode AE. The first layer L1 may be located on the anode electrode AE and the second layer L2. A first surface of the first layer L1 may contact the anode electrode AE. A second surface of the first layer L1 may contact a first surface of the second layer L2.

The first layer L1 may be placed on the pixel defining layer PDL. The first layer L1 may be located between the pixel defining layer PDL and the second separation layer S2. For example, the first layer L1 may overlap the pixel defining layer PDL and the second separation layer S2 in the third direction DR3. The first layer L1 may be located between the pixel defining layer PDL and the first surface of the second separation layer S2. The first surface of the first layer L1 may contact the pixel defining layer PDL. The second surface of the first layer L1 may be spaced apart from the first surface of the second separation layer S2. Space between the second surface of the first layer L1 and the first surface of the second separation layer S2 may form a void.

The second layer L2 may be located on the first layer L1. The second layer L2 may be located between the first layer L1 and the third layer L3. The second layer L2 may be located between the second surface of the first layer L1 and a first surface of the third layer L3. The first surface of the second layer L2 may contact the second surface of the first layer L1, and a second surface of the second layer L2 may contact the first surface of the third layer L3.

The second layer L2 may be located on the second separation layer S2. The second layer L2 may be located between the second separation layer S2 and the fourth separation layer S4. For example, the second layer L2 may overlap the second separation layer S2 and the fourth separation layer S4 in the third direction DR3. The second layer L2 may be located between the second surface of the second separation layer S2 and the first surface of the fourth separation layer S4. According to some embodiments, a first pattern L1′ may be further located between the second separation layer S2 and the second layer L2. The first pattern L1′ located on the second separation layer S2 may be a pattern separated from the first layer L1 by the second separation layer S2 during a process of forming the first layer L1. In this case, the first surface of the second layer L2 may contact the first pattern L1′. According to some embodiments, the first pattern L1′ may also be located on the fourth separation layer S4. The first pattern L1′ located on the fourth separation layer S4 may be a pattern separated from the first layer L1 by the fourth separation layer S4. A second pattern L2′ may be further located on the first pattern L1′. The second pattern L2′ located on the fourth separation layer S4 may be a pattern separated from the second layer L2 by the fourth separation layer S4. A third pattern L3′ may be further located on the second pattern L2′. The third pattern L3′ located on the fourth separation layer S4 may be a pattern separated from the third layer L3 by the fourth separation layer S4.

The third layer L3 may be located on the second layer L2. The third layer L3 may be located between the second layer L2 and the fourth separation layer S4. For example, the third layer L3 may overlap the second layer L2 and the fourth separation layer S4 in the third direction DR3. The third layer L3 may be located between the second surface of the second layer L2 and the first surface of the fourth separation layer S4. The first surface of the third layer L3 may contact the second surface of the second layer L2. A second surface of the third layer L3 may be spaced apart from the first surface of the fourth separation layer S4. Space between the second surface of the third layer L3 and the first surface of the fourth separation layer S4 may form a void.

The third layer L3 may be located on the second separation layer S2. The third layer L3 may be located between the second separation layer S2 and the fourth separation layer S4. For example, the third layer L3 may overlap the second separation layer S2 and the fourth separation layer S4 in the third direction DR3. The third layer L3 may be located between the second surface of the second separation layer S2 and the first surface of the fourth separation layer S4.

A first thickness of the first layer L1 with respect to the third direction DR3 may be different from a second thickness of the second layer L2 with respect to the third direction DR3. For example, the first thickness of the first layer L1 with respect to the third direction DR3 may be less than the second thickness of the second layer L2 with respect to the third direction DR3. A thickness of the first separation layer S1 with respect to the third direction DR3 may be greater than the first thickness of the first layer L1 with respect to the third direction DR3. The thickness of the first separation layer S1 with respect to the third direction DR3 may be less than the sum of the first thickness of the first layer L1 with respect to the third direction DR3 and the second thickness of the second layer L2 with respect to the third direction DR3. A length by which the second separation layer S2 protrudes from the first separation layer S1 may be greater than the second thickness of the second layer L2 with respect to the third direction DR3.

An electrical conductivity of the first layer L1 may be different from an electrical conductivity of the second layer L2. For example, the electrical conductivity of the first layer L1 may be higher than the electrical conductivity of the second layer L2. For instance, the first layer L1 may correspond to a first charge generation layer CGL1′ (refer to FIG. 12), and the second layer L2 may correspond to a second hole transport component HTU2′ (refer to FIG. 12), but embodiments are not limited thereto.

The second thickness of the second layer L2 with respect to the third direction DR3 may be different from a third thickness of the third layer L3 with respect to the third direction DR3. For example, the second thickness of the second layer L2 with respect to the third direction DR3 may be greater than the third thickness of the third layer L3 with respect to the third direction DR3. A thickness of the third separation layer S3 with respect to the third direction DR3 may be greater than the third thickness of the third layer L3 with respect to the third direction DR3.

The electrical conductivity of the second layer L2 may be different from an electrical conductivity of the third layer L3. For example, the electrical conductivity of the second layer L2 may be less than the electrical conductivity of the third layer L3. For instance, the second layer L2 may correspond to the second hole transport component HTU2′ (refer to FIG. 12), and the third layer L3 may correspond to a second charge generation component CGL2′ (refer to FIG. 12), but embodiments are not limited thereto.

According to some embodiments, the second separation layer S2 may be located between the first layer L1 and the second layer L2, whereby the first layer L1 and the second layer L2 may be separated from each other. Accordingly, the third layer L3 may be located on the second layer L2 separated from the first layer L1, so that short-circuit defects occurring between the first layer L1 and the third layer L3 that correspond to relatively high-conductive layers may be prevented or reduced. As a result, the reliability of the sub-pixel can be relatively enhanced.

According to some embodiments, the separation layer SPR may further include a fifth separation layer S5 and/or a sixth separation layer S6. Referring to FIG. 10, the fifth separation layer S5 may be located on the fourth separation layer S4. The fifth separation layer S5 may be located between the fourth separation layer S4 and the sixth separation layer S6. The fifth separation layer S5 may be located between the second surface of the fourth separation layer S4 and a first surface of the sixth separation layer S6. A first surface of the fifth separation layer S5 may contact the second surface of the fourth separation layer S4, and a second surface of the fifth separation layer S5 may contact the first surface of the sixth separation layer S6.

The sixth separation layer S6 may be located on the fifth separation layer S5. The first surface of the sixth separation layer S6 may contact the second surface of the fifth separation layer S5.

A fifth width of the fifth separation layer S5 with respect to the first direction DR1 may be different from the fourth width of the fourth separation layer S4 with respect to the first direction DR1. For example, the fifth width of the fifth separation layer S5 with respect to the first direction DR1 may be less than the fourth width of the fourth separation layer S4 with respect to the first direction DR1.

A sixth width of the sixth separation layer S6 with respect to the first direction DR1 may be different from a fifth width of the fifth separation layer S5 with respect to the first direction DR1. For example, the sixth width of the sixth separation layer S6 with respect to the first direction DR1 may be greater than the fifth width of the fifth separation layer S5 with respect to the first direction DR1.

The fifth separation layer S5 and the sixth separation layer S6 may each include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The fifth separation layer S5 and the sixth separation layer S6 may respectively include different materials. The first separation layer S1, the third separation layer S3, and/or the fifth separation layer S5 may have the same material. The second separation layer S2, the fourth separation layer S4, and/or the sixth separation layer S6 may have the same material, but it is not necessarily limited thereto. For example, the fifth separation layer S5 may be formed of silicon oxide (SiOₓ), and the sixth separation layer S6 may be formed of silicon nitride (SiNₓ), but it is not necessarily limited thereto.

According to some embodiments, the emission structure EMS may include a fourth layer L4 and/or a fifth layer L5.

The fourth layer L4 may be located on the third layer L3. The fourth layer L4 may be located between the third layer L3 and the fifth layer L5. The fourth layer L4 may be located between the second surface of the third layer L3 and a first surface of the fifth layer L5. A first surface of the fourth layer L4 may contact the second surface of the third layer L3, and a second surface of the fourth layer L4 may contact the first surface of the fifth layer L3.

The fourth layer L4 may be located on the fourth separation layer S4. The fourth layer L4 may be located between the fourth separation layer S4 and the sixth separation layer S6. For example, the fourth layer L4 may overlap the fourth separation layer S4 and the sixth separation layer S6 in the third direction DR3. The fourth layer L4 may be located between the second surface of the fourth separation layer S4 and the first surface of the sixth separation layer S6. According to some embodiments, a first pattern L1′, a second pattern L2′, and/or a third pattern L3′ may be further located between the fourth separation layer S4 and the fourth layer L4. The first pattern L1′ located on the fourth separation layer S4 may be a pattern separated from the first layer L1 by the fourth separation layer S4 during a process of forming the first layer L1. The second pattern L2′ located on the fourth separation layer S4 may be a pattern separated from the second layer L2 by the fourth separation layer S4 during a process of forming the second layer L2. The third pattern L3′ located on the fourth separation layer S4 may be a pattern separated from the third layer L3 by the fourth separation layer S4 during a process of forming the third layer L3. The first pattern L1′, the second pattern L2′, and/or the third pattern L3′ may be successively stacked on the fourth separation layer S4. In this case, the first surface of the fourth layer L4 may contact the third pattern L3′.

According to some embodiments, a first pattern L1′ may be further located on the sixth separation layer S6. The first pattern L1′ located on the sixth separation layer S6 may be a pattern separated from the first layer L1 by the sixth separation layer S6. The second pattern L2′ may be further located on the first pattern L1′. The second pattern L2′ located on the sixth separation layer S6 may be a pattern separated from the second layer L2 by the sixth separation layer S6. The third pattern L3′ may be further located on the second pattern L2′. The third pattern L3′ located on the sixth separation layer S6 may be a pattern separated from the third layer L3 by the sixth separation layer S6. A fourth pattern L4′ may be further located on the third pattern L3′. The fourth pattern L4′ located on the sixth separation layer S6 may be a pattern separated from the fourth layer L4 by the sixth separation layer S6. A fifth pattern L5′ may be further located on the fourth pattern L4′. The fifth pattern L5′ located on the sixth separation layer S6 may be a pattern separated from the fifth layer L5 by the sixth separation layer S6.

The fifth layer L5 may be located on the fourth layer L4. The fifth layer L5 may be located between the fourth layer L4 and the sixth separation layer S6. For example, the fifth layer L5 may overlap the fourth layer L4 and the sixth separation layer S6 in the third direction DR3. The fifth layer L5 may be located between the second surface of the fourth layer L4 and the first surface of the sixth separation layer S6. The first surface of the fifth layer L5 may contact the second surface of the fourth layer L4. A second surface of the third layer L5 may be spaced apart from the first surface of the sixth separation layer S6. Space between the second surface of the fifth layer L5 and the first surface of the sixth separation layer S6 may form a void.

The fifth layer L5 may be located on the fourth separation layer S4. The fifth layer L5 may be located between the fourth separation layer S4 and the sixth separation layer S6. For example, the fifth layer L5 may overlap the fourth separation layer S4 and the sixth separation layer S6 in the third direction DR3. The fifth layer L5 may be located between the second surface of the fourth separation layer S4 and the first surface of the sixth separation layer S6.

A fourth thickness of the fourth layer L4 with respect to the third direction DR3 may be different from the third thickness of the third layer L3 with respect to the third direction DR3. For example, the fourth thickness of the fourth layer L4 with respect to the third direction DR3 may be greater than the third thickness of the third layer L3 with respect to the third direction DR3.

A fifth thickness of the fifth layer L5 with respect to the third direction DR3 may be different from the fourth thickness of the fourth layer L4 with respect to the third direction DR3. For example, the fifth thickness of the fifth layer L5 with respect to the third direction DR3 may be less than the fourth thickness of the fourth layer L4 with respect to the third direction DR3.

The thickness of the third separation layer S3 with respect to the third direction DR3 may be less than the sum of the third thickness of the third layer L3 with respect to the third direction DR3 and the fourth thickness of the fourth layer L4 with respect to the third direction DR3. A length by which the fourth separation layer S4 protrudes from the third separation layer S3 may be greater than the fourth thickness of the fourth layer L4 with respect to the third direction DR3. A thickness of the fifth separation layer S5 with respect to the third direction DR3 may be greater than the fifth thickness of the fifth layer L5 with respect to the third direction DR3.

An electrical conductivity of the second layer L4 may be different from the electrical conductivity of the third layer L3. For example, the electrical conductivity of the fourth layer L4 may be less than the electrical conductivity of the third layer L3. An electrical conductivity of the fifth layer L5 may be different from the electrical conductivity of the fourth layer L4. For example, the electrical conductivity of the fifth layer L5 may be higher than the electrical conductivity of the fourth layer L4.

According to some embodiments, the fourth separation layer S4 may be located between the third layer L3 and the fourth layer L4, whereby the third layer L3 and the fourth layer L4 may be separated from each other. Accordingly, the fifth layer L5 may be located on the fourth layer L4 separated from the third layer L3, so that short-circuit defects occurring between the third layer L3 and the fifth layer L5 that correspond to relatively high-conductive layers may be prevented or reduced. As a result, the reliability of the sub-pixel can be relatively enhanced.

Referring again to FIG. 7, the cathode electrode CE may be located on the emission structure EMS. The cathode electrode CE may be provided in common in the first to third sub-pixels SP1 to SP3. The cathode electrode CE may function as a half mirror, partially transmitting and partially reflecting light emitted from the emission structure EMS.

The cathode electrode CE may be connected in the boundary area BDA and thus provided in common in the first to third sub-pixels SP1 to SP3.

The first anode electrode AE1, the portion of the emission structure EMS that overlaps the first anode electrode AE1, and the portion of the cathode electrode CE that overlaps the first anode electrode AE1 may form a first light emitting element LD1. The second anode electrode AE2, the portion of the emission structure EMS that overlaps the second anode electrode AE2, and the portion of the cathode electrode CE that overlaps the second anode electrode AE2 may form a second light emitting element LD2. The third anode electrode AE3, the portion of the emission structure EMS that overlaps the third anode electrode AE3, and the portion of the cathode electrode CE that overlaps the third anode electrode AE3 may form a third light emitting element LD3.

The encapsulation layer TFE may be located on the cathode electrode CE. The encapsulation layer TFE may prevent or reduce instances of contaminants such as oxygen and/or water or the like penetrating into the light-emitting-element layer LDL.

The optical functional layer OFL may be located on the encapsulation layer TFE. According to some embodiments, the optical functional layer OFL may be attached to the encapsulation layer TFE through an adhesive layer APL. For example, the optical functional layer OFL may be fabricated through a separate process and attached to the encapsulation layer TFE by the adhesive layer APL. The adhesive layer APL may further perform a function of protecting underlying layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may transmit light in different wavelength ranges. For example, the first to third color filters CF1 to CF3 may respectively transmit red light, green light, and blue light.

According to some embodiments, the first to third color filters CF1 to CF3 may partially overlap each other in the boundary area BDA. According to some embodiments, the first to third color filters CF1 to CF3 may be spaced apart from each other, and a black matrix may be provided between the first to third color filters CF1 to CF3

The lens array LA may be located on the color filter layer CFL. The lens array LA may include first to third lenses LS1 to LS3 that respectively correspond to the first to third sub-pixels SP1 to SP3. The first to third lenses LS1 to LS3 may respectively direct light emitted from the first to third light emitting elements LD1 to LD3 in intended paths, thus enhancing the light output efficiency.

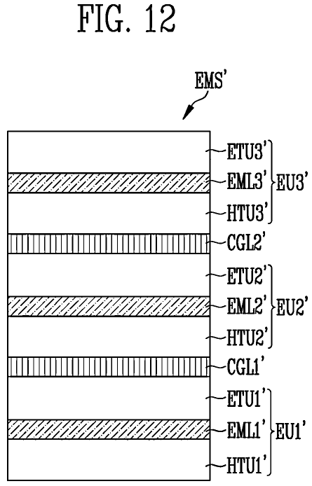

FIG. 11 is a sectional view of an emission structure included in any one of first to third light emitting elements of FIG. 7 according to some embodiments.

Referring to FIG. 11, an emission structure EMS may have a tandem structure in which first and second emission components EU1 and EU2 are stacked. The emission structure EMS may have a substantially identical configuration in each of the first to third light emitting elements LD1 to LD3 of FIG. 7.

Each of the first and second emission components EU1 and EU2 may include at least one emission layer configured to generate light in response to current applied thereto. The first emission component EU1 may include a first emission layer EML1, a first electron transport component ETU1, and a first hole transport component HTU1. The first emission layer EML1 may be located between the first electron transport component ETU1 and the first hole transport component HTU1. The second emission component EU2 may include a second emission layer EML2, a second electron transport component ETU2, and a second hole transport component HTU2. The second emission layer EML2 may be located between the second electron transport component ETU2 and the second hole transport component HTU2.

Each of the first and second hole transport components HTU1 and HTU2 may include at least one of a hole injection layer or a hole transport layer, and may further include a hole buffer layer, an electron blocking layer, and the like, as needed. The first and second hole transport components HTU1 and HTU2 may have the same configuration or have different configurations.

Each of the first and second electron transport components ETU1 and ETU2 may include at least one of an electron injection layer or an electron transport layer, and may further include an electron buffer layer, a hole blocking layer, and the like, as needed. The first and second electron transport components ETU1 and ETU2 may have the same configuration or have different configurations.

A connection layer, which can be provided in the form of a charge generation layer CGL, may be located between the first emission component EU1 and the second emission component EU2 to connect the first and second emission components EU1 and EU2 to each other. According to some embodiments, the charge generation layer CGL may have a stacked structure including a p-dopant layer and an n-dopant layer. For example, the p-dopant layer may include a p-type dopant such as HAT-CN, TCNQ, or NDP-9, and the n-dopant layer may include alkali metal, alkaline earth metal, lanthanide metal, or a combination thereof. However, embodiments are not limited to the aforementioned example.

According to some embodiments, the first emission layer EML1 and the second emission layer EML2 may generate light in different colors. The light emitted from the first emission layer EML1 and the second emission layer EML2 may be mixed to be visible as white light. For instance, the first emission layer EML1 may generate light in blue, and the second emission layer EML2 may generate light in yellow. According to some embodiments, the second emission layer EML2 may include a stacked structure including a first sub-emission layer configured to generate light in red, and a second sub-emission layer configured to generate light in green. Light in red and light in green may be mixed to provide light in yellow. In this case, an intermediate layer configured to perform functions of transporting holes and/or blocking the transport of electrons may be further located between the first and second sub-emission layers. According to some embodiments, the first emission layer EML1 and the second emission layer EML2 may generate light in the same color.

The emission structure EMS may be formed through a scheme such as vacuum deposition, inkjet printing, or the like, but embodiments are not limited thereto.

FIG. 12 is a sectional view of an emission structure included in any one of first to third light emitting elements of FIG. 7 according to some embodiments.

Referring to FIG. 12, an emission structure EMS' may have a tandem structure in which first to third emission components EU1′ and EU3′ are stacked. The emission structure EMS' may have a substantially identical configuration in each of the first to third light emitting elements LD1 to LD3 of FIG. 7.

Each of the first to third emission components EU1′ to EU3′ may include an emission layer configured to generate light in response to current applied thereto. The first emission component EU1′ may include a first emission layer EML1′, a first electron transport component ETU1′, and a first hole transport component HTU1′. The first emission layer EML1′ may be located between the first electron transport component ETU1′ and the first hole transport component HTU1′. The second emission component EU2′ may include a second emission layer EML2′, a second electron transport component ETU2′, and a second hole transport component HTU2′. The second emission layer EML2′ may be located between the second electron transport component ETU2′ and the second hole transport component HTU2′. The third emission component EU3′ may include a third emission layer EML3′, a third electron transport component ETU3′, and a third hole transport component HTU3′. The third emission layer EML3′ may be located between the third electron transport component ETU3′ and the third hole transport component HTU3′.

Each of the first to third hole transport components HTU1′ to HTU3′ may include at least one of a hole injection layer or a hole transport layer, and may further include a hole buffer layer, an electron blocking layer, and the like, as needed. The first to third hole transport components HTU1′ to HTU3′ may have the same configuration or have different configurations.

Each of the first to third electron transport components ETU1′ to ETU3′ may include at least one of an electron injection layer or an electron transport layer, and may further include an electron buffer layer, a hole blocking layer, and the like, as needed. The first to third electron transport components ETU1′ to ETU3′ may have the same configuration or have different configurations.

A first charge generation layer CGL1′ may be located between the first emission component EU1′ and the second emission component EU2′. A second intermediate layer CGL2′ may be located between the second emission component EU2′ and the third emission component EU3′.

According to some embodiments, the first to third emission layers EML1′ to EML3′ may generate light in different colors. Light emitted from the first to third emission layers EML1′ to EML3′ may be mixed to be visible as white light. For example, the first emission layer EML′1 may generate light in blue, the second emission layer EML2′ may generate light in green, and the third emission layer EML3′ may generate light in red. According to some embodiments, two or more emission layers among the first to third emission layers EML1′ to EML3′ may generate light in the same color.

Unlike the case illustrated in FIGS. 11 and 12, the emission structure EMS of FIG. 7 may include one emission component in each of the first to third light emitting elements LD1 to LD3. Here, the respective emission components included in the first to third light emitting elements LD1 to LD3 may be configured to emit light in different colors. For example, the emission component of the first light emitting element LD1 may emit light in red, the emission component of the second light emitting element LD2 may emit light in green, and the emission component of the third light emitting element LD3 may emit light in blue. In this case, the emission components of the first to third sub-pixels SP1 to SP3 may be separated from each other, and each may be located in the corresponding opening OP of the pixel defining layer PDL. In this case, at least some of the color filters CF1 to CF3 may be omitted.

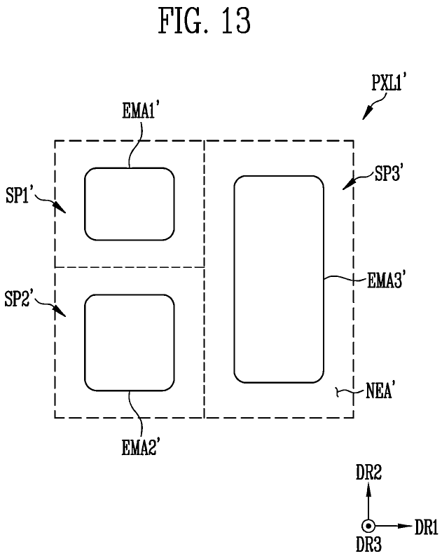

FIG. 13 is a plan view of any one of pixels of FIG. 5 according to some embodiments.

Referring to FIG. 13, a first pixel PXL1′ may include first to third sub-pixels SP1′ to SP3′.

The first sub-pixel SP1′ may include a first emission area EMA1′ and a non-emission area NEA′ formed around the first emission area EMA1′. The second sub-pixel SP2′ may include a second emission area EMA2′ and a non-emission area NEA′ formed around the second emission area EMA2′. The third sub-pixel SP3′ may include a third emission area EMA3′ and a non-emission area NEA′ formed around the third emission area EMA3′.

The first sub-pixel SP1′ and the second sub-pixel SP2′ may be arranged in the second direction DR2. The third sub-pixel SP3′ may be located in the first direction with respect to each of the first and second sub-pixels SP1′ and SP2′.

The second sub-pixel SP2′ may have a larger surface area than the first sub-pixel SP1′. The third sub-pixel SP3′ may have a larger surface area than the second sub-pixel SP2′. Therefore, the second emission area EMA2′ may have a larger surface area than the first emission area EMA1′. The third emission area EMA3′ may have a larger surface area than the second emission area EMA2′. However, embodiments are not limited to the aforementioned example. For example, the first and second sub-pixels SP1′ and SP2′ may have substantially the same surface area. The third sub-pixel SP3′ may have a larger surface area than each of the first and second sub-pixels SP1′ and SP2′. As such, the surface areas of the first to third sub-pixels SP1′ to SP3′ may be changed in various ways depending on embodiments.

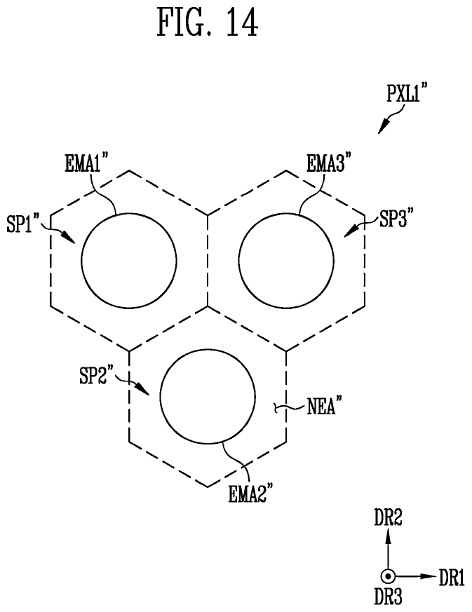

FIG. 14 is a plan view of any one of pixels of FIG. 5 according to some embodiments.

Referring to FIG. 14, a first sub-pixel SP1″ may include a first emission area EMA1″ and a non-emission area NEA″ formed around the first emission area EMA1″. A second sub-pixel SP2″ may include a second emission area EMA2″ and a non-emission area NEA″ formed around the second emission area EMA2″. The third sub-pixel SP3″ may include a third emission area EMA3″ and a non-emission area NEA″ formed around the third emission area EMA3″.

Each of the first to third sub-pixels SP1″ to SP3″ may have a polygonal shape in the third direction DR3. For example, the shapes of the first to third sub-pixels SP1″ to SP3″ may be hexagonal.

Each of the first to third emission areas EMA1″ to EMA3″ may have a circular shape in the third direction DR3. However, embodiments are not limited to the aforementioned example. For example, each of the first to third emission areas EMA1″ to EMA3″ may have a polygonal shape.

The first and third sub-pixels SP1″ and SP3″ may be arranged in the first direction DR1. The second sub-pixel SP2″ may be arranged in a direction (or a diagonal direction) inclined at an acute angle based on the second direction DR2 with respect to the first sub-pixel SP1″.

The arrangements of the sub-pixels illustrated in FIGS. 6, 13, and 14 are illustrative, and embodiments are not limited thereto. Each pixel may include two or more sub-pixels, and the sub-pixels may be arranged in various ways. Each of the sub-pixels may have various shapes. Each of the emission areas of the sub-pixels may also have various shapes.

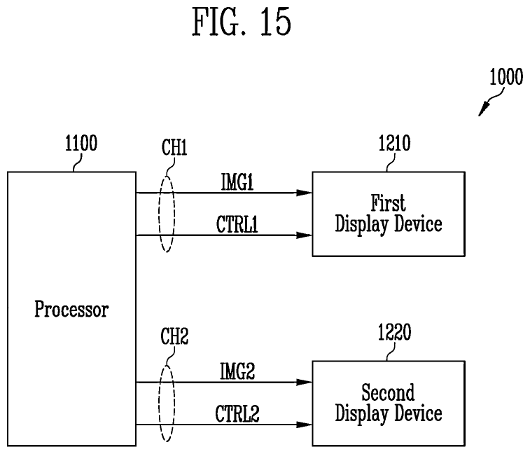

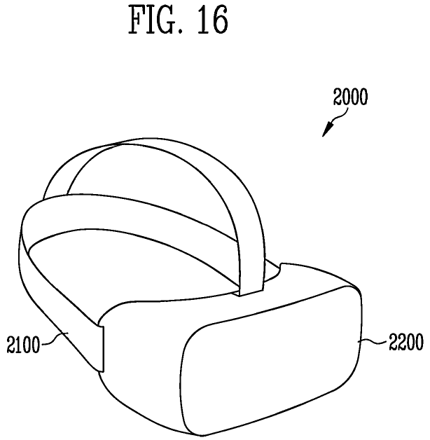

FIG. 15 is a block diagram of a display system according to some embodiments.

Referring to FIG. 15, the display system 1000 may include a processor 1100, and one or more display devices 1210 and 1220.

The processor 1100 may perform various tasks and operations. According to some embodiments, the processor 1100 may include an application processor, a graphic processor, a microprocessor, a central processing unit (CPU), and so on. The processor 110 may be connected to the other components of the display system 1000 through a bus system to control the components.

In FIG. 15, there is illustrated the case where the display system 1000 includes the first and second display devices 1210 and 1220. The processor 1100 may be connected to the first display device 1210 through a first channel CH1, and may be connected to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured in the same manner as the display device 100 described with reference to FIG. 1. In this case, the first image data IMG1 and the first control signal CTRL1 may be provided as the input image data IMG and the control signal CTRL of FIG. 1, respectively.

The processor 1100 may transmit second image data IMG2 and a second control signal CTRL2 to the second display device 1220 through the second channel CH2. The second display device 1220 may display an image based on the second image data IMG2 and the second control signal CTRL2. The first display device 1220 may be configured in the same manner as the display device 100 described with reference to FIG. 1. In this case, the second image data IMG2 and the second control signal CTRL2 may be provided as the input image data IMG and the control signal CTRL of FIG. 1, respectively.

The display system 1000 may include computing systems that provide an image display function, such as a portable computer, a mobile phone, a smart phone, a tablet personal computer (tablet PC), a smart watch, a watch phone, a portable multimedia player, a navigation system, and an ultra mobile personal computer (UMPC). Furthermore, the display system 1000 may include at least one of a head-mounted display (HMD), a virtual reality (VR) device, a mixed reality (MR) device, or an augmented reality (AR) device.

FIG. 16 is a perspective view of an application example of a display system of FIG. 15 according to some embodiments.

Referring to FIG. 16, the display system 1000 of FIG. 15 may be applied to a head mounted display device 2000. The head mounted display device 2000 may be a wearable electronic device, which can be worn on the head of the user.

The head mounted display 2000 may include a head mounted band 2100 and a display device reception casing 2200. The head mounted band 2100 may be connected to the display device reception casing 220. The head mounted band 2100 may include a horizontal band and/or a vertical band to fasten the head mounted display 2000 to the head of the user. The horizontal band may enclose the sides of the head of the user, and the vertical band may enclose the top of the head of the user. However, embodiments are not limited to the aforementioned example. For example, the head mounted band 2100 may be implemented in the form of eyeglass frames, a helmet, and so on.

The display device reception casing 2200 may receive the first and second display devices 1210 and 1220 of FIG. 15. The display device reception casing 2200 may further receive the processor 1100 of FIG. 12.

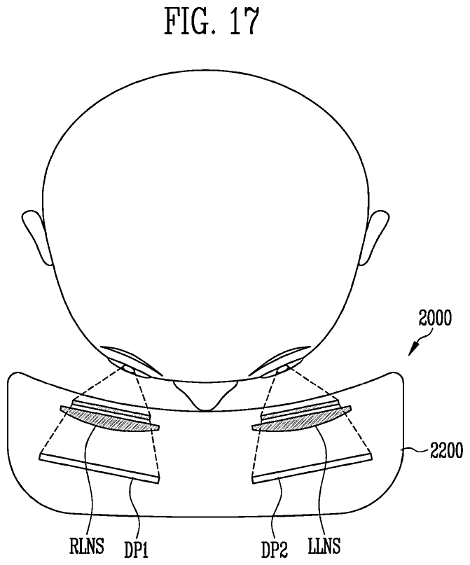

FIG. 17 is a diagram of a head-mounted display device of FIG. 16 that is worn on a user according to some embodiments.

Referring to FIG. 17, the first display panel DP1 of the first display device 1210 and the second display panel DP2 of the second display device 1220 are located in the head-mounted display device 2000. The head mounted display 2000 may further include one or more lenses LLNS and RLNS.

In the display device reception casing 2200, the right-eye lens RLNS may be positioned between the first display panel DP1 and the right eye of the user. In the display device reception casing 2200, the left-eye lens LLNS may be positioned between the second display panel DP1 and the left eye of the user.

An image outputted from the first display panel DP1 can be viewed by the right eye of the user through the right-eye lens RLNS. The right lens RLNS may refract light emitted from the first display panel DP1 toward the right eye of the user. The right-eye lens RLNS may perform an optical function to adjust a viewing distance between the first display panel DP1 and the right eye of the user.

An image outputted from the second display panel DP2 can be viewed by the left eye of the user through the left-eye lens LLNS. The left lens LLNS may refract light emitted from the second display panel DP2 toward the left eye of the user. The left-eye lens LLNS may perform an optical function to adjust a viewing distance between the second display panel DP2 and the left eye of the user.

According to some embodiments, each of the right-eye lens RLNS and the left-eye lens LLNS may include an optical lens having a pancake-shaped cross-section. According to some embodiments, each of the right-eye lens RLNS and the left-eye lens LLNS may include a multi-channel lens including sub-areas having different optical characteristics. In this case, each display panel may output images respectively corresponding to sub-areas of the multi-channel lens. The output images may be viewed to the user through the corresponding sub-areas.

According to some embodiments, portions of an emission structure may be separated from each other by a separation layer formed in a boundary area between adjacent sub-pixels. Accordingly, current leaking to adjacent sub-pixels may be minimized or reduced.

However, aspects and features of the present disclosure are not limited to those described above, and various other aspects and features would be understood by one of ordinary skill in the art within the spirit and scope of the present disclosure.

The embodiments described in detail above are provided to explain the present disclosure, but these embodiments are not intended to limit the scope of the present disclosure. It should be understood by those skilled in the art that various changes, substitutions, and alternations may be made therein without departing from the scope of the disclosure as defined by the following claims and their equivalents.

The scope of embodiments according to the present disclosure is not limited by detailed descriptions of the present specification and should be defined by the accompanying claims and their equivalents. Furthermore, all changes or modifications of the present disclosure derived from the claims, and equivalents thereof, should be construed as being included in the scope of embodiments according to the present disclosure. The embodiments may be combined to form additional embodiments.

What is claimed is:

1. A display device, comprising:
a first electrode;
a pixel defining layer on the first electrode;
a separation layer on the pixel defining layer;
an emission structure on the first electrode and the separation layer; and
a second electrode on the emission structure,
wherein the separation layer comprises a first separation layer on the pixel defining layer and having a first width, and a second separation layer on the first separation layer and having a second width greater than the first width,
wherein the emission structure includes a first layer having a first thickness, and a second layer having a second thickness greater than the first thickness, and
wherein the second separation layer is between the first layer and the second layer.

2. The display device according to claim 1, wherein a thickness of the first separation layer is greater than the first thickness.

3. The display device according to claim 1, wherein a thickness of the first separation layer is less than a sum of the first thickness and the second thickness.

4. The display device according to claim 1, wherein the first layer is between the pixel defining layer and the second separation layer.

5. The display device according to claim 1, wherein the separation layer further includes a third separation layer on the second separation layer and having a third width less than the second width, and a fourth separation layer on the third separation layer and having a fourth width greater than the third width.

6. The display device according to claim 5, wherein the second layer is between the second separation layer and the fourth separation layer.

7. The display device according to claim 5, wherein the emission structure further includes a third layer having a third thickness less than the second thickness, and a fourth layer having a fourth thickness greater than the third thickness.

8. The display device according to claim 7, wherein the fourth separation layer is between the third layer and the fourth layer.

9. The display device according to claim 7, wherein the third layer is between the second layer and the fourth separation layer.

10. The display device according to claim 9, wherein a thickness of the third separation layer is greater than the third thickness.

11. The display device according to claim 9, wherein a thickness of the third separation layer is less than a sum of the third thickness and the fourth thickness.

12. A display device, comprising:
a first electrode;
a pixel defining layer on the first electrode;
a separation layer on the pixel defining layer;
an emission structure on the first electrode and the separation layer; and
a second electrode on the emission structure,
wherein the separation includes a first separation layer having a first width, and a second separation layer having a second width greater than the first width,
wherein the emission structure includes a first layer between the pixel defining layer and a first surface of the second separation layer, and a second layer on the a second surface of the second separation layer, and
wherein an electrical conductivity of the first layer is higher than an electrical conductivity of the second layer.

13. The display device according to claim 12, wherein the first separation layer is between the pixel defining layer and the second separation layer.

14. The display device according to claim 12, wherein the separation layer further includes a third separation layer having a third width less than the second width.

15. The display device according to claim 14, wherein the third separation layer is on the second surface of the second separation layer.

16. The display device according to claim 14, wherein the separation layer further includes a fourth separation layer having a fourth width greater than the third width.

17. The display device according to claim 16, wherein the third separation layer is between the second separation layer and the fourth separation layer.

18. The display device according to claim 16, wherein the emission structure further includes a third layer between the second surface of the second separation layer and a first surface of the fourth separation layer.

19. The display device according to claim 18, wherein the emission structure further includes a fourth layer on a second surface of the fourth separation layer.

20. The display device according to claim 19, wherein an electrical conductivity of the third layer is higher than an electrical conductivity of the fourth layer.
